(19) United States
(12) Patent Application Publication
(10) Pub. No.: US 2006/0017119 A1
(43) Pub. Date: Jan. 26, 2006

(54) Multi-gate transistor and method of fabricating multi-gate transistor

(76) Inventors: You-seung Jin, Seoul (KR); Shigaenobu Maeda, Seongnam-si (KR)

Correspondence Address: HARNESS, DICKEY & PIERCE, P.L.C., P.O. BOX 8910, RESTON, VA, 20195, US

(21) Appl. No.: 11/188,722

(22) Filed: Jul. 26, 2005

(30) Foreign Application Priority Data
Jul. 26, 2004 (KR) 10-2004-0058257

(51) Int. Cl. H01L 29/76

(52) U.S. Cl. 257/401

(57) ABSTRACT

A multi-gate transistor and a method of fabricating the multi-gate transistor may involve forming an active pattern with a multi-channel region, in which a channel region is provided on at least two surfaces of the active pattern. An interconnect may be connected to an interconnect region of the active pattern excluding the multi-channel region.

### PRIORITY STATEMENT

This application claims priority from Korean Patent Application No. 10-2004-0058257 filed on Jul. 26, 2004 in the Korean Intellectual Property Office, the disclosure of which is incorporated herein by reference in its entirety.

### BACKGROUND

1. Field of the Invention

The present invention relates generally to a method of fabricating a multi-gate transistor that may provide improved performance and a multi-gate transistor fabricated by the method.

2. Description of the Related Art

Multi-gate transistors may have a double-gate structure or a tri-gate structure, for example. Multi-gate transistors may reduce degradation of performance due to a reduction of a gate length (Lg), for example, that may be associated with miniaturized devices.

A conventional single-gate planar transistor may require a depleted region thickness (Tsi) less than ⅓ of a gate length (Lg). Accordingly, when the gate length (Lg) is reduced, a thin silicon body may be needed. As compared to a single-gate transistor, an active structure of a multi-gate transistor may have an increased tolerance on the fully depleted region thickness (Tsi).

Referring to FIG. 1, an active structure of a multi-gate transistor may be formed using a mask 10 with active region patterns 12 that may be subjected to optical proximity correction. FIG. 2 is a schematic diagram illustrating a photoresist pattern 20 that may be formed using the mask 10 shown in FIG. 1. Referring to FIG. 2, a profile of a bar pattern 22 (which may define a region where a channel region may be formed) may be curved due to limitations to optical proximity correction in photolithography, for example. In addition, a hole profile may appear between bar patterns 22. Moreover, critical dimensions (CD) of the bar patterns 22 may not be uniform. As a result, as shown in FIGS. 3A and 3B, an active structure 30 formed using the photoresist pattern 20 as an etch mask may have the same shortcomings. When misalignment occurs (e.g., when a gate electrode 40 is formed on the active structure 30), as shown in FIGS. 3A and 3B, performance of a transistor may be changed and/or adversely affected. In addition, in an etching process, silicon may remain in an active region, as shown in FIG. 4A, and/or the active region may not be open, as shown in FIG. 4B, due to a hole profile, for example.

Accordingly, a method of forming the active region with stable profile reproducibility and uniform critical dimensions may be desirable.

### SUMMARY

According to an example, non-limiting embodiment of the present invention, a method may involve forming an active pattern having a multi-channel region, in which a channel region may be provided on at least two surfaces of the active pattern. An interconnect may be connected to an interconnect region of the active pattern excluding the multi-channel region.

According to another example, non-limiting embodiment, a method may involve forming a plurality of linear spaced apart active patterns. A gate insulating layer may be formed on at least two surfaces of each of the linear spaced apart active patterns. A gate electrode may be formed on the gate insulating layer. Impurities may be implanted into each of the active patterns exposed by the gate electrode to form source/drain regions. An interconnect may be formed on interconnect regions of the active patterns excluding regions of the active patterns where the gate insulating layer and the gate electrode are formed.

According to another example, non-limiting embodiment of the present invention, a method of fabricating a multi-gate transistor of a memory device may involve forming a plurality of spaced apart active patterns. Gate insulating layers may be formed on at least two surfaces of each of the active patterns. Gate electrodes may be formed on the gate insulating layers. Impurities may be implanted into each of the active patterns exposed by each of the gate electrodes to form source/drain regions. An interconnect may be formed connecting the source/drain regions of the active patterns.

According to another example, non-limiting embodiment of the present invention, a multi-gate transistor may include an active pattern with a multi-channel region, in which a channel region may be provided on at least two surfaces of the active pattern. An interconnect may be connected to an interconnect region of the active pattern excluding the multi-channel region.

According to another example, non-limiting embodiment of the present invention, a multi-gate transistor may include a plurality of spaced apart linear active patterns. A gate insulating layer may be provided on at least two surfaces of each of the plurality of spaced apart linear active patterns. A gate electrode may be provided on the gate insulating layer. Source/drain regions may be formed in each of the spaced apart linear active patterns exposed by the gate electrode. An interconnect may be provided on interconnect regions of the spaced apart linear active patterns excluding regions of the spaced apart linear active patterns where the gate insulating layer and the gate electrode is provided.

According to another example, non-limiting embodiment of the present invention, a multi-gate transistor of a memory device may include a plurality of spaced apart active patterns. Gate insulating layers may be provided on at least two surfaces of each of the plurality of active patterns. Gate electrodes may be provided on the gate insulating layers. Source/drain regions may be provided in each of the active patterns exposed by the gate electrodes. An interconnect may connect the source/drain regions of the active patterns.

### BRIEF DESCRIPTION OF THE DRAWINGS

Example, non-limiting embodiments of the present invention will be readily understood with reference to the following detailed description thereof provided in conjunction with the accompanying drawings, wherein like reference numerals designate like structural elements

FIG. 1 illustrates a mask pattern defining an active region for a conventional multi-gate transistor.

FIG. 2 is a schematic diagram of a photoresist pattern defined by the mask pattern of FIG. 1.

FIGS. 3A through 4B are scanning electron microscope (SEM) photographs of the active region that may be formed according to a conventional fabricating method.

FIG. 5 is a flow chart of a method that may be implemented to fabricate a multi-gate transistor according to an example, non-limiting embodiment of the present invention.

FIG. 6 illustrates an exposure layout that may be implemented in a method of fabricating a tri-gate transistor according to an example, non-limiting embodiment of the present invention.

FIGS. 7 through 19 are schematic perspective views of intermediate structures that may result in the method of fabricating the tri-gate transistor according to the example, non-limiting embodiment of the present invention.

FIG. 20 is a schematic perspective view of a method that may be implemented to fabricate a double-gate transistor according to another, example, non-limiting embodiment of the present invention.

FIG. 21 is an equivalent circuit diagram of a static random access memory (SRAM) cell to which a fabrication method according to another example, non-limiting embodiment of the present invention may be applied.

FIGS. 22A, 22B and 22C illustrate exposure layouts of an active pattern, a gate pattern and a mold pattern that may be implemented for forming an interconnect of the SRAM cell to which the example, non-limiting embodiment of the present invention may be applied.

FIGS. 23 through 26B are perspective views of intermediate structures that may result in the fabrication method according to the example, non-limiting embodiment of the present invention.

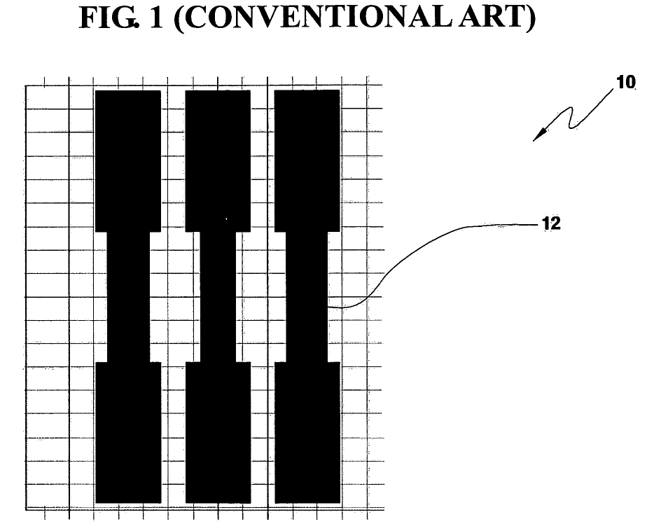

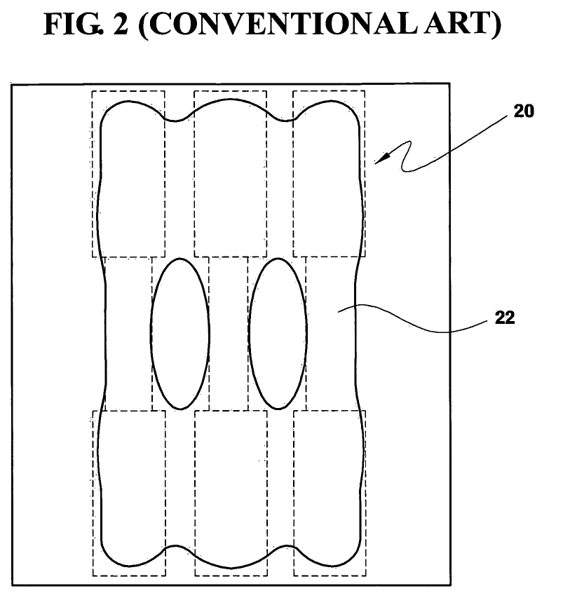

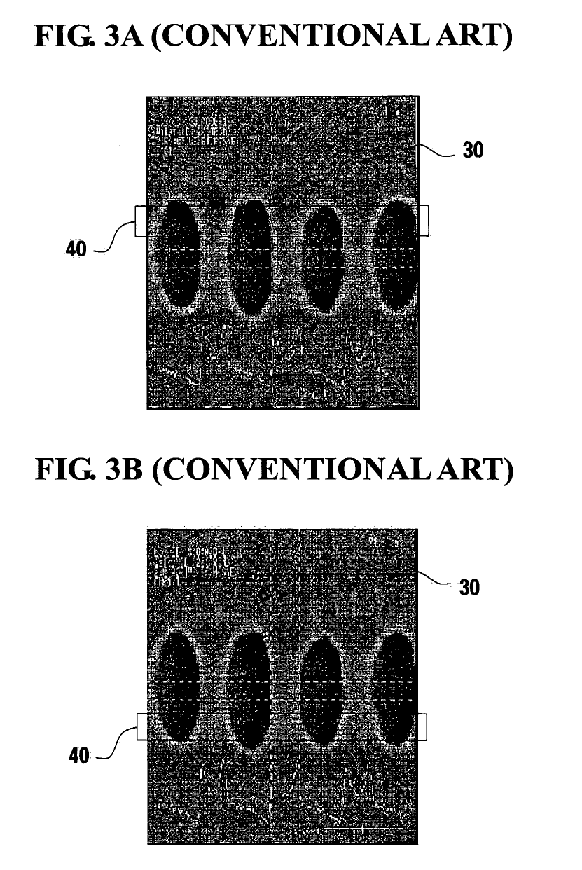

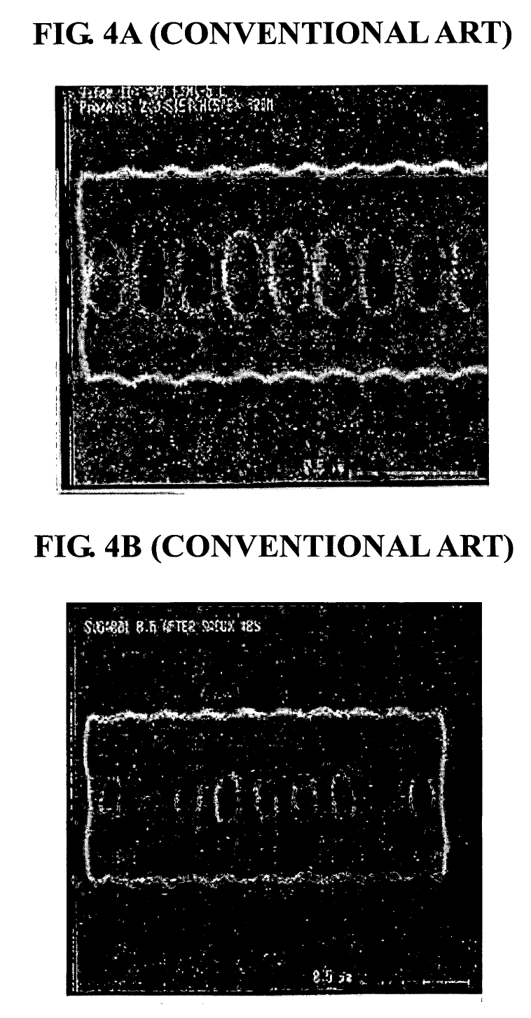

The drawings are provided for illustrative purposes only and are not drawn to scale. The spatial relationships and relative sizing of the elements illustrated in the various embodiments may have been reduced, expanded or rearranged to improve the clarity of the figure with respect to the corresponding description. The figures, therefore, should not be interpreted as accurately reflecting the relative sizing or positioning of the corresponding structural elements that could be encompassed by an actual device manufactured according to the example, non-limiting embodiments of the invention.

### DETAILED DESCRIPTION OF EXAMPLE, NON-LIMITING EMBODIMENTS OF THE INVENTION

Example, non-limiting embodiments of the present invention will be described in detail with reference to the accompanying drawings. The present invention may, however, be embodied in many different forms and should not be construed as being limited to the example embodiments set forth herein. Rather, these embodiments are provided so that this disclosure will be thorough and complete and will fully convey the concept of the invention to those skilled in the art, and the present invention will only be defined by the appended claims. The principles and features of this invention may be employed in varied and numerous example embodiments without departing from the scope of the invention.

Well-known structures and processes are not described or illustrated in detail to avoid obscuring the present invention.

An element is considered as being mounted (or provided) “on” another element when mounted (or provided) either directly on the referenced element or mounted (or provided) on other elements overlaying the referenced element. Throughout this disclosure, the terms “top,” “bottom” and “side” are used for convenience in describing various elements or portions or regions of the elements as shown in the figures. These terms do not, however, require that the structure be maintained in any particular orientation.

A method of fabricating an active structure with more reliable profile reproducibility and more uniform critical dimensions, and an active structure and a multi-gate transistor with improved performance which may be fabricated using the method will be described by explaining example, non-limiting embodiments of the present invention.

According to example, non-limiting embodiments of the present invention, a region where a channel region may be formed on at least two surfaces and a region that may be affected little by optical proximity may be formed in a mesa-type active pattern, for example. The mesa-type active pattern may be a line-and-space pattern, for example. Accordingly, a profile of an active region where the channel region may be formed may be straight (for example), and uniform critical dimensions may be accomplished. Active patterns may be interconnected by an interconnect, for example. The interconnect may allow, for example, a source/drain region contact to be formed along sidewalls and edges of the active patterns, thereby improving the source/drain region contact characteristics, for example.

Multi-gate transistors to which a method of fabricating an active structure according to the present invention may be applied include, for example, a double-gate transistor having channel regions on two surfaces of an active pattern and a tri-gate transistor having channel regions on three surfaces of an active pattern.

The multi-gate transistors may include transistors used in highly integrated semiconductor memory devices such as a dynamic random access memory (DRAM) device, a static RAM (SRAM) device, a flash memory device, a ferroelectric RAM (FRAM) device, a magnetic RAM (MRAM) device, and a parameter RAM (PRAM) device, micro electro mechanical system (MEMS) devices, optoelectronic devices, display devices, and processors such as a central processing unit (CPU) and a digital signal processor (DSP), for example. The embodiments of the present invention may be used to fabricate an active structure of a transistor for a logic device or an SRAM device utilizing a great driving current to achieve fast operation.

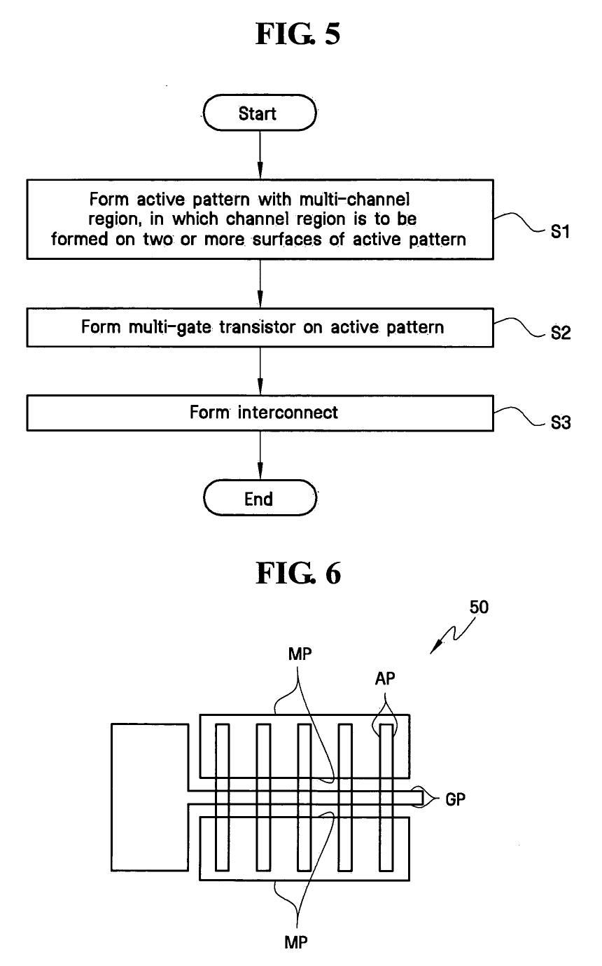

Exemplary embodiments of the present invention will be understood best with reference to FIGS. 5 through 26B. FIG. 5 is a flow chart of a method that may be implemented to fabricate a multi-gate transistor according to example, non-limiting embodiments of the present invention. FIG. 6 illustrates an exposure layout that may be implemented in a method of fabricating a tri-gate transistor of a logic device (for example) according to an example, non-limiting embodiment of the present invention. FIGS. 7 through 19 are schematic perspective views of intermediate structures that may result in the method according to the example, non-limiting embodiment of the present invention.

The example, non-limiting embodiment may be directed to a method that may be implemented to fabricate an active structure of a tri-gate transistor. A tri-gate transistor may allow for increased fabrication margin since tri-gate transistor may have increased tolerances on a depleted region thickness (Tsi) as well as increased width (Wsi), thereby lowering an aspect ratio of the active structure. An example, non-limiting embodiment may be applicable to a method of fabricating an active structure of a tri-gate transistor for a logic device utilizing fast operation.

As shown in FIG. 5, the example method may involve forming an active pattern that may have a multi-channel region, in which channel regions may be formed on two or more surfaces of the active pattern (at S1). A multi-gate transistor may be formed on the active pattern (at S3). An interconnect may be provided to electrically interconnect to the active pattern (at S3).

The formation of the active pattern will be described with reference to FIGS. 6 through 8.

FIG. 6 illustrates an example exposure layout 50. The exposure layout 50 may include an exposure active pattern AP, an exposure gate pattern GP, and an exposure interconnect mold pattern MP.

Referring to FIG. 7, a photoresist pattern 110 may be provided on a silicon layer 102, for example. The photoresist pattern 110 may be formed by projecting an image of the exposure active pattern AP shown in FIG. 6 onto a photoresist layer provided on the substrate. The silicon layer 102 may be a silicon layer stacked on SOI insulating layer 101 on a bulk silicon substrate (not shown) to enhance a drain induced barrier lowering (DIBL) effect in a tri-gate transistor, for example. The SOI substrate may be formed, for example, using a bonding process or a Separation by IMplantation of OXygen (SIMOX) process. The silicon layer 102 may be fabricated from only silicon or silicon together with germanium, for example. Instead of the SOI substrate, a bulk silicon substrate or a silicon germanium substrate may be used, for example.

Referring to FIG. 8, the silicon layer 102 may be etched using the photoresist pattern 110 as an etch mask, thereby forming an active pattern 102a on which a channel region may be formed. The active pattern 102a may have a mesa shape including, for example, two sidewalls that may extend up to a top surface. Here, the top surface of the active pattern 102a may be elevated above the insulating layer 101. A bottom surface of the active pattern 102a may contact the insulating layer 101. In an example embodiment, the active pattern 102a may have a top surface that is perpendicular to the sidewalls. In alternative embodiments, the top surface may be inclined relative to the sidewalls, the sidewalls may taper, and/or the top surface and the sidewalls may be of any geometric shape. As will be described in more detail below, channel regions may be formed in the top surface and one or more of the sidewalls of the active pattern 102. In an example embodiment, the active pattern 102a may be formed in a line pattern having a straight profile and uniform critical dimensions. For a logic device, for example, a plurality active patterns 102a may be provided in a line-and-space pattern, and a pitch between adjacent active patterns 102a may be less than about 300 nm, for example. In alternative embodiments, the active patterns 102 may not have a straight line configuration.

A multi-gate transistor may be formed on the active pattern 102a (S2 in FIG. 5).

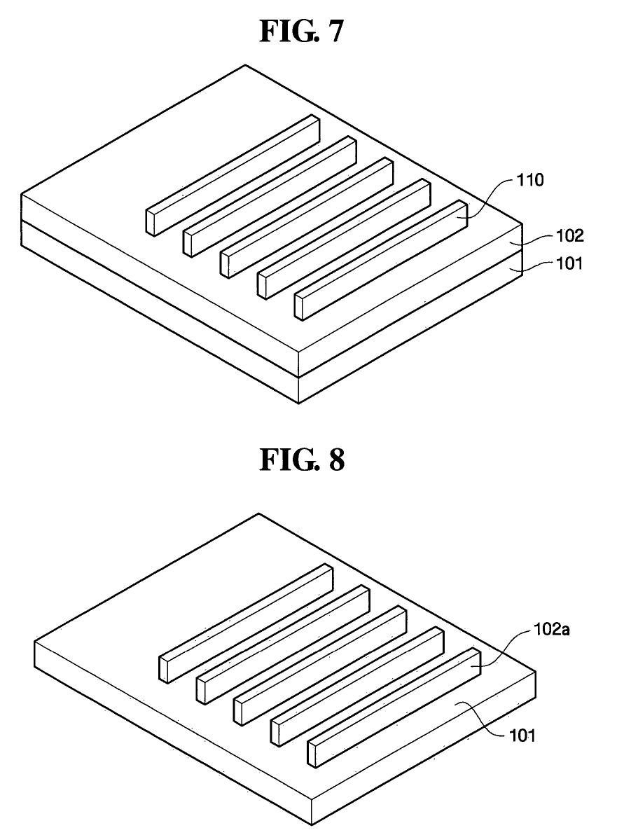

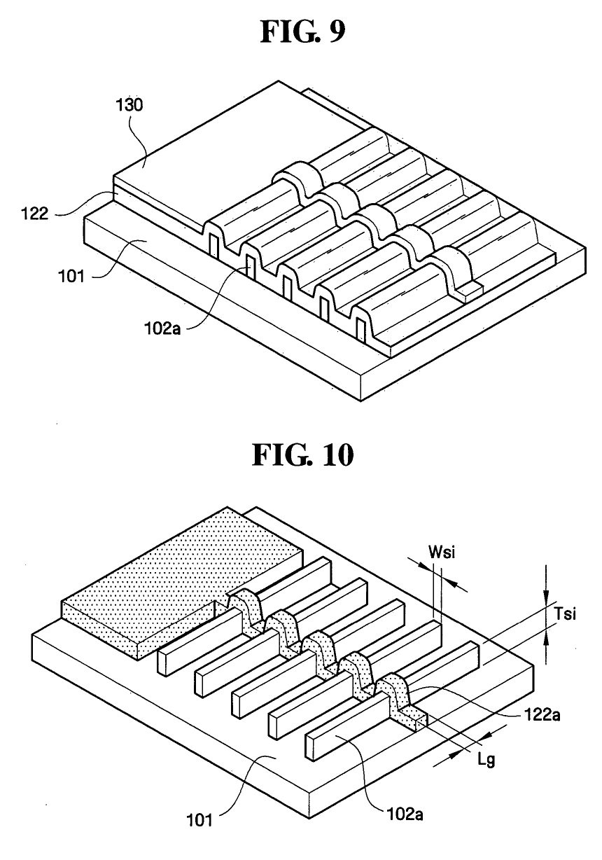

In an example embodiment, the multi-gate transistor may be in the form of a tri-gate transistor, as will be described with reference to FIGS. 9 through 11.

Referring to FIG. 9, ions for adjusting a threshold voltage may be implanted on an entire surface of a resultant structure on which the active pattern 102a is formed. A gate insulating layer (not shown) and a gate electrode conducting layer 122 may be formed on an entire surface of the active pattern 102a and at least a portion of the insulating layer 101. A photoresist pattern 130 may be provided on the gate electrode conducting layer 122. The photoresist pattern 130 may be formed by projecting an image of the exposure gate pattern GP shown in FIG. 6 onto a photoresist layer provided on the gate electrode conducting layer 122.

The gate insulating layer (not shown) may be formed using an oxide layer, a thermally grown silicon dioxide layer, silk, polyimide, or a high dielectric material layer, for example. The high dielectric material layer may be formed by forming an Al₂O₃ layer, a Ta₂O₅ layer, an HfO₂ layer, a ZrO₂ layer, a hafnium silicate layer, a zirconium silicate layer, or a combination thereof using atomic layer deposition, for example.

The gate electrode conducting layer 122 may be formed by using only a doped polysilicon layer or a metal layer, by sequentially stacking a doped polysilicon layer and a metal layer, or by sequentially stacking a doped polysilicon layer and a metal silicide layer, for example. The metal layer may be fabricated from a tungsten layer, a cobalt layer, or a nickel layer, for example. Suitable examples of the metal silicide layer may include a tungsten silicide layer, a cobalt silicide layer, and a nickel silicide layer, for example. The doped polysilicon layer may be formed by LPCVD using SiH₂Cl₂ and PH₃ gas, for example. As shown in FIG. 9, the gate electrode conducting layer 122 may conform to a stepped profile of the active pattern 102a. For example, the gate electrode conducting layer 122 may contact sidewalls and the top surface of the active pattern 102a.

Referring to FIG. 10, the gate electrode conducting layer 122 may be etched using the photoresist pattern 130 as an etch mask, thereby forming a gate electrode 122a. The photoresist pattern 130 may be removed.

The gate electrode 122a may overlap (and contact) opposite sidewalls and top surfaces of the active patterns 102a, which may have a thickness Tsi and a width Wsi. The gate electrode 122a may have a gate length Lg. The gate electrode 122a may be commonly disposed on the successively arranged active patterns 102a. The channel regions of each active pattern 102a may be located on those regions of the top surface and the sidewalls of the active pattern 102a that may exist below the gate electrode 122a.

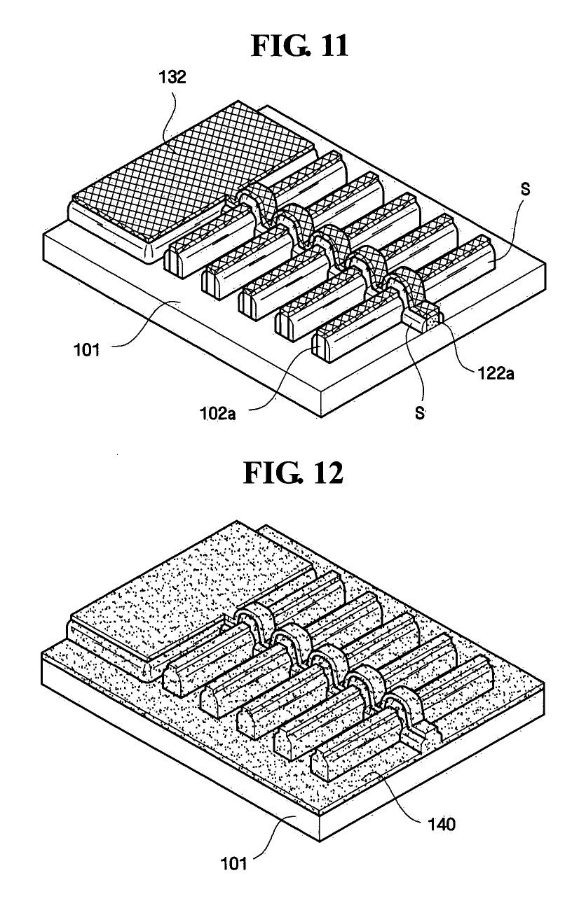

In an example, non-limiting embodiment, and referring to FIG. 11, source/drain regions may be formed via two ion implantation processes. By way of example only, impurities (for forming extension source/drain regions) may be implanted into the portions of the active pattern 102a that are exposed by the gate electrode 122a. Subsequently, a spacer S (forming an insulating layer) may be formed on sidewalls of the gate electrode 122a existing between the active patterns 102a and the sidewalls of the active patterns 102a by an etch-back process, for example. Next, impurities may be implanted using the gate electrode 122a and the spacer S as an ion implantation mask.

As occasion demands, a process for forming a silicide layer 132 (which may reduce resistances of the gate electrode 122a and/or the source/drain region) may be implemented.

An interconnect for electrically interconnecting the active patterns 102a may be formed (S3 of FIG. 5).

The forming of the interconnect will be described with reference to FIGS. 12 through 19.

Referring to FIG. 12, an etch stop layer 140 may be formed on a surface of the structure depicted in FIG. 11. The etch stop layer 140 may be fabricated from silicon nitride or silicon oxynitride, for example. The etch stop layer 140 may have a thickness of several tens to several hundreds of angstroms, for example. The etch stop layer 140 may be fabricated using chemical vapor deposition (CVD) techniques, for example. The etch stop layer 140 may serve as an etch stopper when forming a mold mask.

Referring to FIG. 13, a mold layer 150 may be formed on a surface of the structure depicted in FIG. 12. The mold layer 150 may be formed using a material having etch selectivity with respect to the etch stop layer 140 and step deposition characteristic, and may be, for example, from an oxide material. The mold layer 150 may be formed to a thickness of several hundreds to thousands of angstroms, for example. The mold layer 150 may be fabricated using CVD techniques, for example. A process for planarizing the mold layer 150 may be optionally implemented. The planarization process may be performed in such a way that the top surface of the gate electrode 122a is not exposed. A mask layer 160 may be formed on a top surface of the mold layer 150. The mask layer 160 can be formed to a thickness of several tens to hundreds of angstroms, for example. The mask layer 160 may be formed using a material having etch selectivity with respect to the mold layer 150. The mask layer 160 may be, for example, a nitride layer. The mask layer 160 may be formed to compensate for a lack of etching tolerance of a photoresist pattern in an etching process for patterning the mold layer 150 into an interconnect forming mold. Accordingly, the forming of the hard mask layer 160 may be omitted according to conditions of the etching process for forming the interconnect mold.

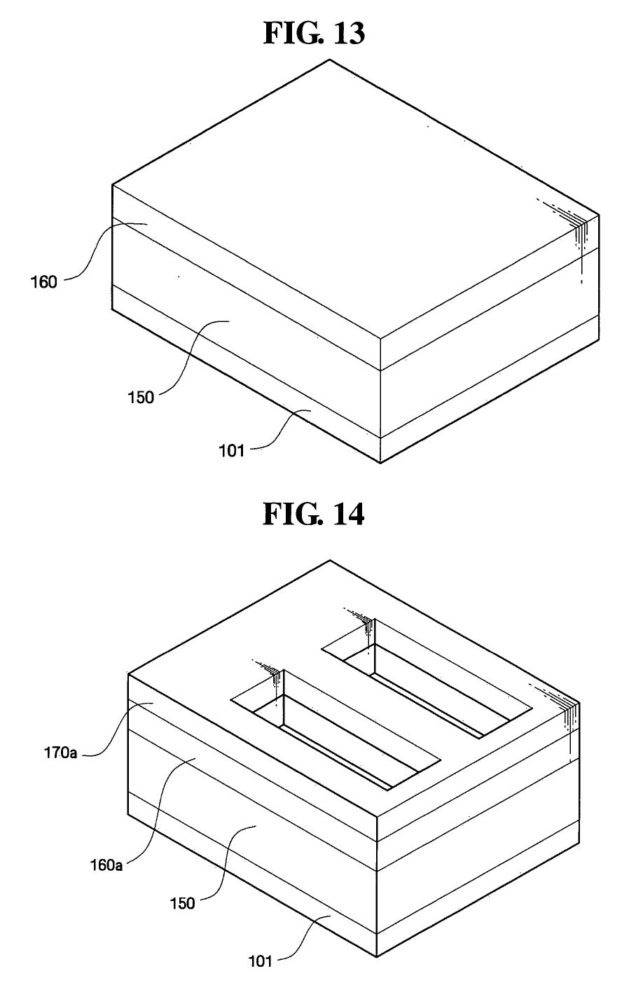

Referring to FIG. 14, a photoresist pattern 170a may be provided on the mask layer 160. The photoresist pattern 170a may be formed by projecting an image of the exposure mold pattern MP shown in FIG. 6 onto a photoresist layer provided on the mask layer 160. The mask layer 160 may be etched using the photoresist pattern 170a as an etch mask, thereby forming a mask 160a.

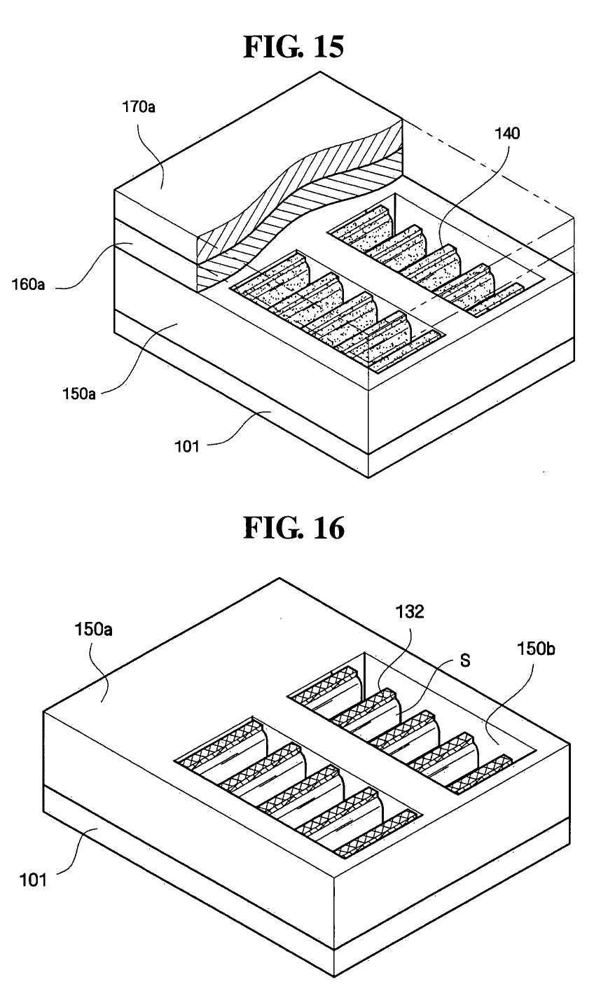

Referring to FIG. 15, the mold layer 150 may be etched using the photoresist pattern 170a and the mask 160a as an etch mask, thereby forming an interconnect mold 150a. The etch stop layer 140 may prevent the active pattern 102a from being etched and/or damaged by the etching process for forming the interconnect mold 150a. Accordingly, if exact time control on the etching process is possible, the formation of the etch stop layer 140 may be eliminated.

Referring to FIG. 16, the photoresist pattern 170a may be removed using an ashing process and a strip process, for example. The mask 160a may be removed. A cleaning process may be performed. During the cleaning process, the etch stop layer 140 exposed by the interconnect mold 150a may be removed. Removal of the etch stop layer 140 may be optionally performed before the cleaning process. The spacer S may be removed from the sidewalls of the active patterns 102a by an etching process and/or a cleaning process, for example. The interconnect mold 150a may have an open region 150b where an interconnect may be formed.

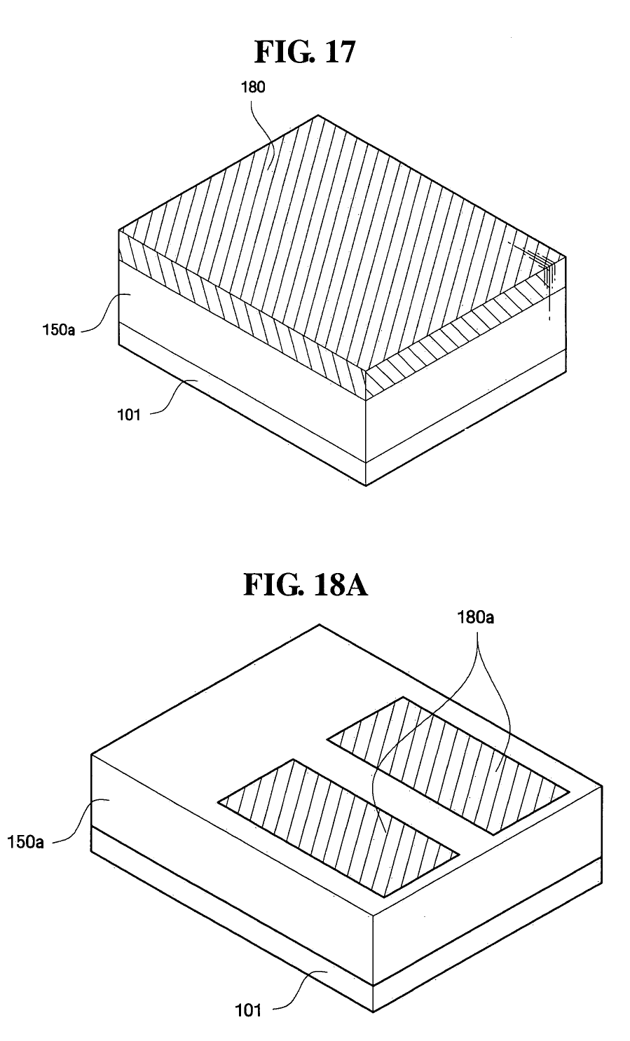

Referring to FIG. 17, a conductive layer 180 may be formed on the surface of the structure depicted in FIG. 16. The conductive layer 180 may include a diffusion barrier layer and a metal layer, for example. The diffusion barrier layer may be formed using Ti, TiN, for example, and the metal layer may be formed using tungsten, for example. The conductive layer 180 may be formed to a thickness which may fill the open region 150b of the interconnect mold 150a.

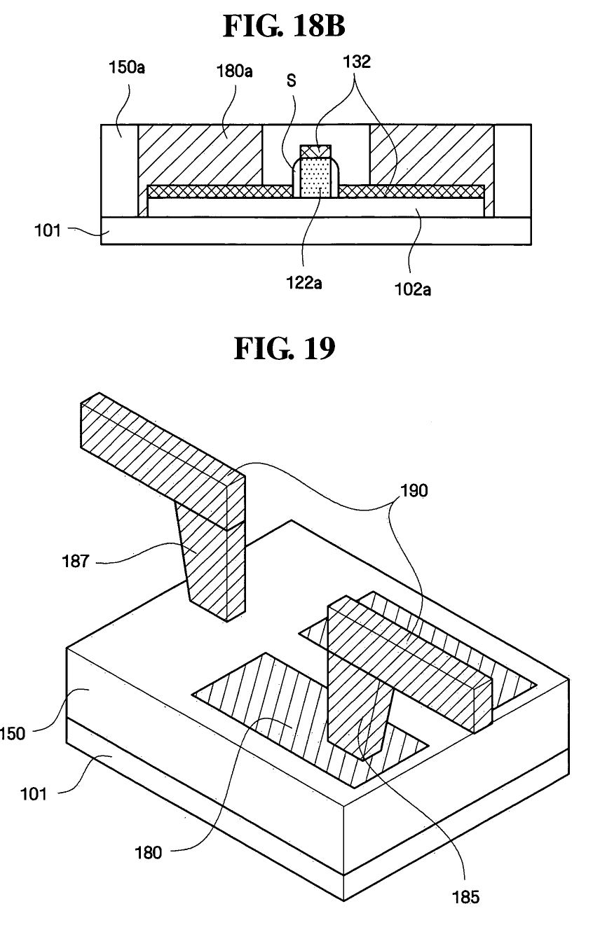

Referring to FIGS. 18A and 18B, a process for planarizing the conductive layer 180 may be performed. A source/drain contact may be formed along sidewalls and top surfaces of the active patterns 102a, on which the source/drain regions are formed, excluding the channel regions of the active patterns 102a. In this way, the interconnect 180a may improve the source/drain contact characteristics, for example.

Referring to FIG. 19, an interlayer insulating layer (not shown) may be formed. A contact plug 185 may contact the source/drain region. A contact plug 187 may contact the gate electrode 122a. Upper interconnects 190 may be formed. The interlayer insulating layer (not shown), the contact plugs 185, 187 and the upper interconnects 190 may be fabricating using conventional processes.

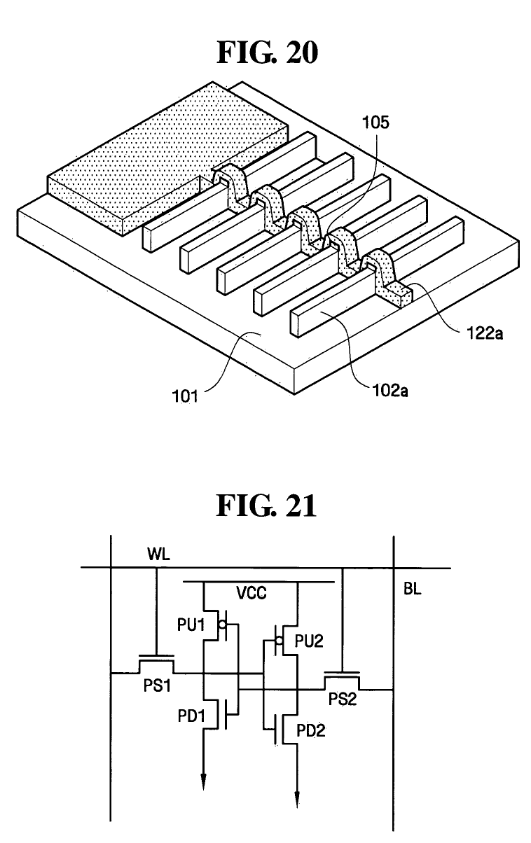

FIG. 20 is a schematic perspective view of a method that may be implemented to fabricate an active structure of a double-gate transistor according to another example, non-limiting embodiment of the present invention.

In the double-gate transistor, channel regions may be formed only on the sidewalls of the active pattern 102a. With the exception described below, the fabrication method of the active structure of the double-gate transistor according to an example embodiment may be similar to that of the tri-gate transistor of the previous example embodiment. Before forming the photoresist pattern 110 (refer to FIG. 7) (e.g., by projecting the image of the exposure active pattern AP (refer to FIG. 6) onto a photoresist layer), an insulating layer 105 may be formed on the silicon layer (102 shown in FIG. 7). The insulating layer 105 and the silicon layer 102 may be etched using the photoresist pattern 110 as an etch mask, thereby forming the active pattern 102a having a top surface on which is provided the insulating layer 105. Accordingly, the channel regions of each active pattern 102a may be located on those regions of the sidewalls of the active pattern 102a that may exist below the gate electrode 122a.

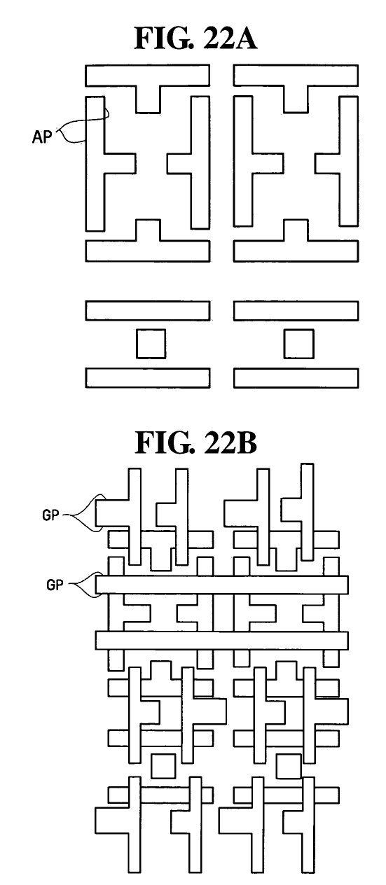

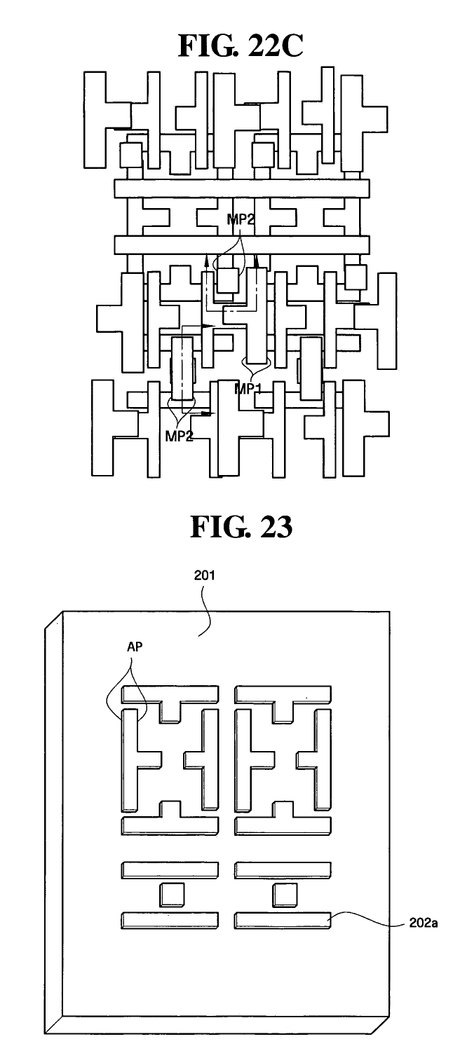

FIGS. 21 through 26 illustrate a method that may be implemented to fabricate a tri-gate transistor for a static random access memory (SRAM) cell according to another example, non-limiting embodiment of the present invention. FIG. 21 is an equivalent circuit diagram of the SRAM cell, and FIGS. 22A, 22B and 22C illustrate exposure layouts of an exposure active pattern AP, an exposure gate pattern GP and an exposure interconnect mold pattern MP, respectively. FIGS. 23 through 26B are perspective views of intermediate structures that may result in the method of fabricating the tri-gate transistor for the SRAM cell.

Referring to FIG. 21, a full CMOS SRAM cell may include two pull-up transistors PU1 and PU2, two pull-down transistors PD1 and PD2, and two pass (or access) transistors PS1 and PS2, a word line WL, a bit line BL, and a power supply voltage line Vcc.

The method of fabricating the tri-gate transistor according to an example, non-limiting embodiment will be described with reference to FIGS. 22A through 26. The portions of the example method that may be similar to those of the fabricating method of the tri-gate transistor of the previous example embodiment will be omitted.

As shown in FIG. 23, an active pattern 202a may be provided on a SOI substrate 201. The active pattern 202a may be formed by projecting an image of the exposure active pattern AP shown in FIG. 22A onto a photoresist layer to form a photoresist pattern (not shown) and then etching a silicon layer (using the photoresist pattern as an etch mask) that may be provided on the SOI substrate 201. The active pattern 202a may include a portion where a channel region of a tri-gate transistor may be formed. The active pattern 202a may be formed using a combination of line patterns, for example. A photoresist pattern, for forming a well, may be formed, thereby implanting ions for forming an N-well and a P-well, respectively.

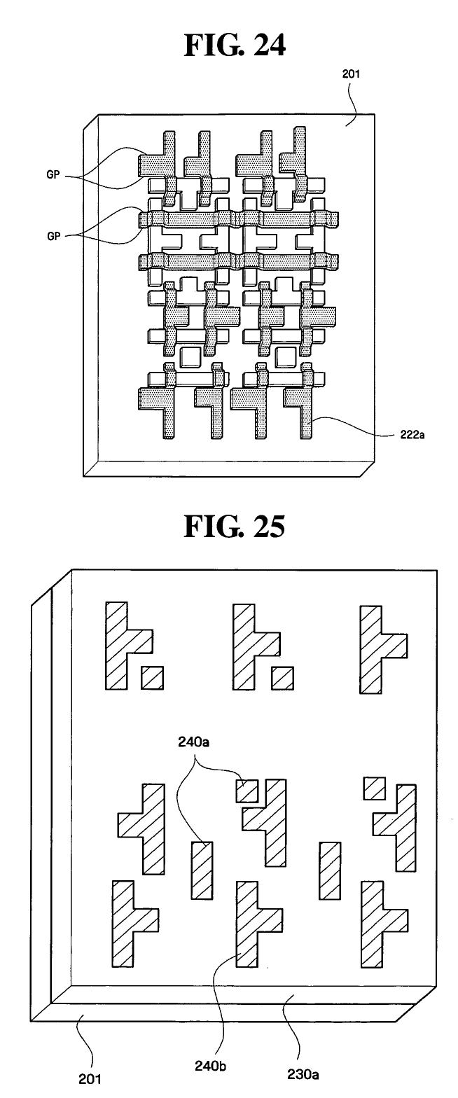

Referring to FIG. 24, a gate insulating layer and a gate electrode conducting layer may be formed on a surface of the structure depicted in FIG. 23. Here, a photoresist layer may be patterned by projecting an image of the exposure gate pattern GP shown in FIG. 20B onto the photoresist layer. The gat electrode conducting layer may be etched using the photoresist layer as an etch mask, thereby forming a gate electrode 222a. The gate electrode 222a may conform to a stepped profile of the active pattern 202a. The gate electrode 22a may overlap (and contact) opposite sides and a top surface of the active pattern 202a.

Although not shown in the drawings, a photoresist pattern for ion implantation may be formed, and ions for forming source/drain regions may be implanted into a region of an NMOS transistor and a region of a PMOS transistor using the photoresist pattern and the gate electrode as an ion implantation mask, respectively. A spacer may be formed on a sidewall of the gate electrode 222a. A photoresist pattern for ion implantation may be formed, and ions for forming source/drain regions may be implanted into the region of the NMOS transistor and the region of the PMOS transistor using the photoresist pattern, the gate electrode, and the spacer as an ion implantation mask, respectively. A silicide layer may be formed on top surfaces of the gate electrode 222a and the source/drain regions, respectively.

Referring to FIG. 25, an interconnect 240 may formed. An interlayer insulating layer may be formed on a surface of the substrate 201, and photolithographic etching may be performed, thereby forming interconnect molds 230a to which images of first and the second exposure mold patterns MP1 and MP2 shown in FIG. 22C may be projected and transferred. As shown in FIG. 22C, the first exposure mold pattern MP1 may define an interconnect connecting the source/drain regions of the active patterns 202a which may be separated from one another according to the different gate electrodes 222a. The second exposure mold pattern MP2 may define an interconnect connecting a source/drain regions of an active pattern 202a to a top surface of the gate electrodes 222a arranged on an active pattern 202a different from the active pattern 202a. A conductive layer may be provided in an open region of the molds 230. The conductive layer may be fabricated from Ti/TiN/W, for example. The conductive layer may be planarized using a CMP process, for example, to form interconnects 240a and 240b.

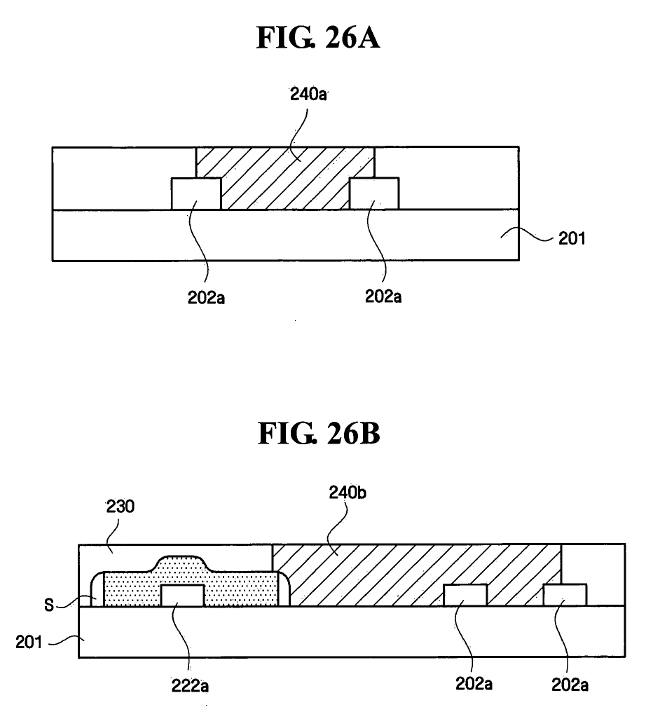

FIG. 26A is a cross-sectional view of the interconnect 240a that may connect the source/drain regions of the active patterns 202a which may be separated from one another according to the different gate electrodes 222a, and FIG. 26B is a cross-sectional view of the interconnect 240b that may connect a source/drain region of an active pattern 202a to a top surface of the gate electrodes 222a arranged on an active pattern 202a different from the active pattern 202a. According to an example embodiment, a portion of the active pattern 202a where a channel region is to be formed may be formed using patterning, for example. Accordingly, the channel region of the active pattern may have a desired profile and more uniform critical dimensions. By way of example only, most of the active patterns 202a may be formed using a combination of line patterns, and a portion that may be affected by an optical proximity effect may be formed as an interconnect. In this way, the resulting transistor may have improved performance. Further, the size of an SRAM cell may be reduced, for example, by using interconnects connecting source/drain regions of adjacent transistors to one another and/or connecting the source/drain regions to gate electrodes of the adjacent transistors. In this way, it may be possible to improve integration density of a device. Further, an interconnect may be formed within a one-layer insulating layer formed above a multi-gate transistor using a damascene process. Accordingly, a fabrication process of the interconnect may be simplified, a defect may be reduced in which an active pattern may not open, and the occurrence of a bridge caused by a misalignment between a contact pad and the interconnect may be reduced.

While example, non-limiting embodiments of the present invention have been particularly shown and described with reference to the accompanying drawings, it will be understood by those of ordinary skill in the art that various changes in form and details may be made therein without departing from the spirit and scope of the present invention as defined by the following claims.

What is claimed is:

1. A method comprising:
forming an active pattern having a multi-channel region, in which a channel region is provided on at least two surfaces of the active pattern; and
forming an interconnect connected to an interconnect region of the active pattern excluding the multi-channel region.

2. The method of claim 1, wherein the active pattern is a linear pattern.

3. The method of claim 2, wherein the active pattern is a plurality of spaced apart linear patterns; and
wherein the interconnect connects together the plurality of linear patterns.

4. The method of claim 1, wherein forming the active pattern comprises:
providing a silicon layer on an insulator wafer; and
patterning the silicon layer to form the active pattern.

5. The method of claim 1, wherein forming the interconnect comprises:
masking the multi-channel region of the active pattern;
forming an insulating mold exposing the interconnect region of the active pattern; and
forming the interconnect covering the interconnect region exposed by the insulating mold.

6. A method comprising:
forming a plurality of linear spaced apart active patterns;
forming a gate insulating layer on at least two surfaces of each of the linear spaced apart active patterns;
forming a gate electrode on the gate insulating layer;
implanting impurities into each of the active patterns exposed by the gate electrode to form source/drain regions;
forming an interconnect on interconnect regions of the active patterns excluding regions of the active patterns where the gate insulating layer and the gate electrode are formed.

7. The method of claim 6, wherein the interconnect connects together the active patterns.

8. The method of claim 6, wherein forming of the plurality of linear space apart active patterns comprises:
providing a silicon layer on an insulator wafer; and
patterning the silicon layer to form the active patterns.

9. The method of claim 6, wherein forming the interconnect comprises:
providing an insulating mold to cover the gate electrode and expose the interconnect regions of the active patterns; and
forming the interconnect covering the interconnect regions exposed by the insulating mold.

10. The method of claim 6, further comprising, forming a silicide layer on at least one of an upper part of the gate electrode and an upper part of the source/drain regions, before forming the interconnect.

11. A method of fabricating a multi-gate transistor of a memory device comprising:
forming a plurality of spaced apart active patterns;
forming gate insulating layers on at least two surfaces of each of the active patterns;
forming gate electrodes on the gate insulating layers;
implanting impurities into each of the active patterns exposed by each of the gate electrodes to form source/drain regions;
forming an interconnect connecting the source/drain regions of the active patterns.

12. The method of claim 11, wherein forming the active patterns comprises:
providing a silicon layer on an insulator substrate; and
patterning the silicon layer to form the active patterns.

13. The method of claim 11, wherein forming the interconnect comprises:
providing an insulating mold to cover the gate electrodes and expose the source/drain regions of the active patterns; and
forming the interconnect covering the source/drain regions exposed by the insulating mold.

14. The method of claim 11, further comprising, forming a silicide layer on at least one of an upper part of the gate electrodes and an upper part of the source/drain regions, before forming the interconnect.

15. The method of claim 11, wherein the interconnect connects together the source/drain regions of one active pattern and a surface of the gate electrode arranged on another active pattern.

16. The method of claim 11, wherein the memory device is a static random access memory (SRAM).

17. A multi-gate transistor comprising:
an active pattern having a multi-channel region, in which a channel region is provided on at least two surfaces of the active pattern; and
an interconnect connected to an interconnect region of the active pattern excluding the multi-channel region.

18. The multi-gate transistor of claim 17, wherein the active pattern has vertical sidewalls.

19. The multi-gate transistor of claim 17, wherein the active pattern is a linear pattern.

20. The multi-gate transistor of claim 19, wherein the active pattern is a plurality of spaced apart linear patterns.

21. The multi-gate transistor of claim 20, wherein the plurality of spaced apart linear patterns are interconnected by the interconnect.

22. The multi-gate transistor of claim 17, wherein the active pattern is mesa-shaped.

23. The multi-gate transistor of claim 22, wherein the active pattern is fabricated from silicon provided on an insulator wafer.

24. The multi-gate transistor of claim 23, wherein the channel regions are provided on one of both sidewalls of the active pattern and both sidewalls and a top surface of the active pattern.

25. A multi-gate transistor comprising:
a plurality of spaced apart linear active patterns;
a gate insulating layer provided on at least two surfaces of each of the plurality of spaced apart linear active patterns;
a gate electrode provided on the gate insulating layer;
source/drain regions formed in each of the spaced apart linear active patterns exposed by the gate electrode; and
an interconnect provided on interconnect regions of the spaced apart linear active patterns excluding regions of the spaced apart linear active patterns where the gate insulating layer and the gate electrode is provided.

26. The multi-gate transistor of claim 25, wherein the spaced apart linear active patterns are mesa-shaped.

27. The multi-gate transistor of claim 26, wherein the spaced apart and linear active patterns are fabricated from silicon provided on an insulator wafer.

28. The multi-gate transistor of claim 27, wherein channel regions are provided on one of both sidewalls each of the spaced apart linear active patterns and on both sidewalls and a top surface of each of the spaced apart linear active patterns.

29. A multi-gate transistor of a memory device comprising:
a plurality of spaced apart active patterns;
gate insulating layers provided on at least two surfaces of each of the plurality of active patterns;
gate electrodes provided on the gate insulating layers;
source/drain regions provided in each of the active patterns exposed by the gate electrodes; and
an interconnect connecting the source/drain regions of the active patterns.

30. The multi-gate transistor of claim 29, wherein the active patterns have vertical sidewalls.

31. The multi-gate transistor of claim 29, wherein the active patterns are linear patterns.

32. The multi-gate transistor of claim 29, wherein the active patterns are mesa-shaped.

33. The multi-gate transistor of claim 32, wherein the active patterns are fabricated from silicon provided on an insulator wafer.

34. The multi-gate transistor of claim 33, wherein channel regions are provided on one of both sidewalls of each of the active patterns and both sidewalls and a top surface of each of the active patterns.

35. The multi-gate transistor of claim 29, wherein the interconnect connects together the source/drain regions of one active pattern to a surface of the gate electrode arranged on another active pattern.

36. The multi-gate transistor of claim 29, wherein the memory device is a static random access memory (SRAM).
